(19) United States
(12) Patent Application Publication
(10) Pub. No.: US 2012/0235688 A1
(43) Pub. Date: Sep. 20, 2012

(54) APPARATUS FOR DETECTING PARTIAL DISCHARGE SIGNAL AND METHOD THEREOF

(75) Inventor: Do Hoon LEE, Cheongju (KR)

(73) Assignee: LSIS CO., LTD., Anyang-Si (KR)

(21) Appl. No.: 13/420,463

(22) Filed: Mar. 14, 2012

(30) Foreign Application Priority Data
Mar. 18, 2011 (KR) 10-2011-0024593

(51) Int. Cl. G01R 27/28

(52) U.S. Cl. 324/619

(57) ABSTRACT

An apparatus for detecting a partial discharge (PD) signal capable of detecting a PD signal of a power device includes: a partial discharge (PD) coupler connected to a ground side of a power device and configured to cancel a low frequency noise component including a commercial frequency from an AC component flowing through the ground side of the power device when a partial PD signal is generated from the power device, and to allow a high frequency component including a PD signal included in the AC component to pass therethrough to generate a PD analog signal; and a PD detection unit configured to cancel a noise signal from the PD analog signal generated by the PD coupler to detect only the PD signal.

### CROSS REFERENCE TO RELATED APPLICATIONS

Pursuant to 35 U.S.C. §119(a), this application claims the benefit of earlier filing date and right of priority to Korean Patent Application No. 10-2011-0024593, filed on Mar. 18, 2011, the contents of which are hereby incorporated by reference herein in its entirety.

1. Field of the Invention

The present invention relates to an apparatus for detecting a partial discharge signal and a method thereof.

2. Description of the Related Art

In general, in a method for detecting a partial discharge signal of a power device, a partial discharge signal is detected by using a coupler and high frequency C.T (HFCT) (or an RFCT) connected to a high voltage part of a power device. However, when a power device in which a coupler is connected to a high voltage part is applied to high capacity/high voltage facilities, the coupler is increased in size and high-priced. Also, since the coupler is directly connected to the high voltage part of the power device, an accident in which the coupler is exploded occurs frequently. In addition, since the coupler is required to come into contact with the high voltage part, an interruption to service work (or a dead-line work) is required to apply the coupler to an existing power device which is installed and operated.

### SUMMARY OF THE INVENTION

According to an aspect of the present invention, there is provided an apparatus for detecting a partial discharge signal of a power device, including: a partial discharge (PD) coupler connected to a ground side (i.e., an earthing side or a connection grounded side) of a power device, and configured to cancel a low frequency noise component including a commercial frequency from an alternating current (AC) component flowing through the ground side of the power device when a partial PD signal is generated from the power device, and allow a high frequency component including a PD signal included in the AC component to pass therethrough to generate a PD analog signal; and a PD detection unit configured to cancel a noise signal from the PD analog signal generated by the PD coupler to detect only the PD signal.

In an example in relation to the present disclosure, the PD coupler may be a coupling capacitor in which mica is laminated or a ceramic material is laminated (or a coupling capacitor made of mica or a ceramic material).

In an example in relation to the present disclosure, the apparatus may further include: a display unit configured to display information corresponding to the PD signal on a screen.

In an example in relation to the present disclosure, the PD detection unit may include: a high frequency filter connected to the PD coupler and configured to cancel an external noise signal from the PD analog signal received from the PD coupler and output an analog signal including the PD signal; an analog-to-digital (A/D) converter configured to convert the analog signal output from the high frequency filter into a digital signal; a controller configured to detect the PD signal from the digital signal which has been converted by the A/D converter, and generate information corresponding to the detected PD signal; and a display unit configured to display the information corresponding to the detected PD signal on a screen.

In an example in relation to the present disclosure, the information corresponding to the detected PD signal may be a digital value corresponding to the detected PD signal or a signal graph corresponding to the detected PD signal.

According to another aspect of the present invention, there is provided a method for detecting a partial discharge signal of a power device, including: when a partial discharge (PD) signal is generated from a power device through a PD coupler connected to a ground side of the power device, canceling a low frequency noise component including a commercial frequency from an alternating current (AC) component flowing through the ground side of the power device; generating a PD analog signal by allowing a high frequency component including a PD signal included in the AC component to pass through the PD coupler connected to the ground side of the power device; and canceling a noise signal from the generated PD analog signal to detect only the PD signal.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view showing the configuration of an apparatus for detecting a partial discharge (PD) signal of a power device according to an embodiment of the present invention.

FIG. 2 is a schematic block diagram showing the configuration of a PD detection unit according to an embodiment of the present invention.

FIG. 3 is a flow chart illustrating the process of a method for detecting a PD signal of a power device according to an embodiment of the present invention.

### DETAILED DESCRIPTION OF THE INVENTION

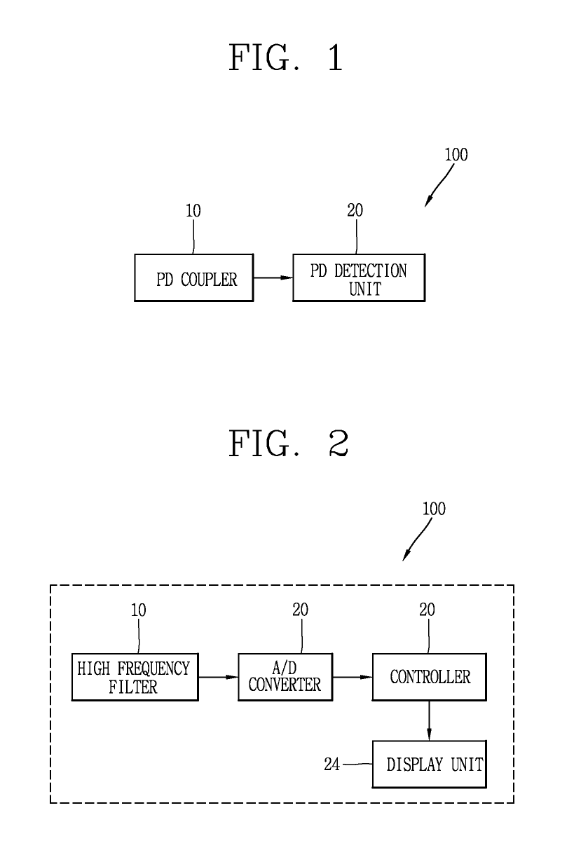

An apparatus and method for detecting a partial discharge (PD) signal capable of detecting a PD signal of a power device by connecting a PD coupler having high frequency characteristics and high sensitivity characteristics to a ground side (i.e., an earthing side or a connection grounded side) of the power device, to thus prevent a breakdown (damage) of the power device and/or the PD coupler, minimize the size of the PD coupler, reduce the cost of the PD coupler, and easily apply the PD coupler to a power device that is in operation, according to embodiments of the present invention will be described with reference to FIGS. 1 to 3.

FIG. 1 is a view showing the configuration of an apparatus for detecting a partial discharge (PD) signal of a power device according to an embodiment of the present invention.

As shown in FIG. 1, an apparatus 100 for detecting a partial discharge (PD) signal of a power device (e.g., a high voltage power device) according to an embodiment of the present invention may include a partial discharge (PD) coupler (e.g., a contact type PD coupler) 10 connected to a ground side (i.e., an earthing side or a connection grounded side) of a power device, and configured to cancel a low frequency noise component including a commercial frequency and allow a high frequency component including a PD signal to pass therethrough to generate a PD analog signal; and a PD detection unit 20 configured to cancel a noise signal from the PD analog signal output from the PD coupler 10 to detect only the PD signal.

The apparatus 100 for detecting a PD signal of a power device (e.g., a high voltage power device) according to an embodiment of the present invention is used to detect a PD signal generated from the high voltage power device having a ground through the PD coupler 10 to determine whether or not the produce (e.g., the high voltage power device) is electrically abnormal. For example, the PD coupler 10 according to an embodiment of the present invention is connected to a ground side of the power device, and when a PD signal is generated in the power device, the PD coupler 10 cancels a low frequency component including a commercial frequency from an alternating current (AC) component flowing through the ground side of the power device and allows a high frequency component including a PD signal included in the AC component to pass therethrough to output a PD analog signal (or a PD pulse analog signal).

The PD coupler 10 may be connected to the ground side of the power device and may be configured as a coupling capacitor in which mica is laminated or a ceramic material is laminated.

FIG. 2 is a schematic block diagram showing the configuration of the PD detection unit 20 according to an embodiment of the present invention.

As shown in FIG. 2, the PD detection unit 20 according to an embodiment of the present invention includes: a high frequency filter 21 connected to the PD coupler 20 and configured to cancel an external noise signal from the PD analog signal received from the PD coupler 20 and output an analog signal including the PD signal; an analog-to-digital (A/D) converter 22 configured to convert the analog signal output from the high frequency filter 21 into a digital signal and output the digital signal; a controller 23 configured to detect the PD signal from the digital signal which has been converted by the A/D converter 22, and generate information (which is a digital value corresponding to the detected PD signal or a signal graph corresponding to the detected PD signal) corresponding to the detected PD signal; and a display unit 24 configured to display the information corresponding to the detected PD signal on a screen.

A method for detecting a PD signal of a power device according to an embodiment of the present invention will be described with reference to FIGS. 1 to 3.

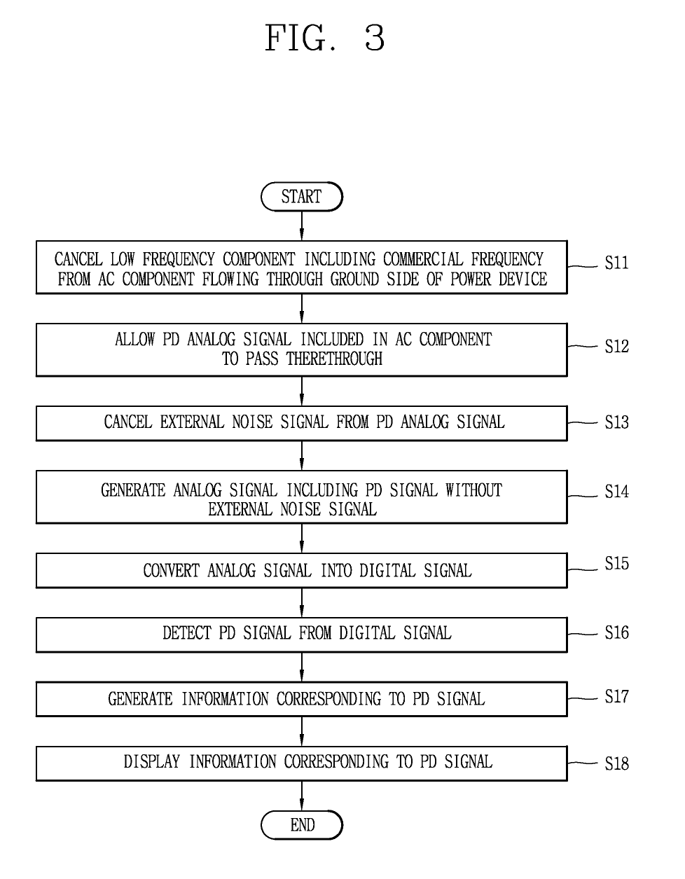

FIG. 3 is a flow chart illustrating the process of a method for detecting a PD signal of a power device according to an embodiment of the present invention.

First, the PD coupler 10 is connected to the ground side of the power device, and when a PD signal is generated from the power device, the PD coupler 10 cancels a low frequency component including a commercial frequency from an AC component flowing through the ground side of the power device (step S11).

The PD coupler 10 allows a high frequency component including a PD signal included in the AC component to pass therethrough to generate a PD analog signal (or a PD pulse analog signal) and output the PD analog signal to the high frequency filter 21 (step S12).

The high frequency filter 21 is connected to the PD coupler 20, cancels an external noise signal from the PD pulse analog signal received from the PD coupler 20 to generate an analog signal including a PD signal, and outputs the analog signal to the A/D converter 22 (steps S13 and S14).

The A/D converter 22 converts the analog signal output from the high frequency filter 21 into a digital signal, and outputs the digital signal to the controller 23 (step S15).

The controller 23 detects the PD signal from the digital signal output from the A/D converter 22 (step S16), generates information (which is a digital value corresponding to the detected PD signal or a signal graph corresponding to the detected PD signal) corresponding to the detected PD signal (step S17), and outputs the information corresponding to the PD signal to the display unit 24.

The display unit 24 displays the information corresponding to the detected PD signal on the screen (step S18).

As described above, in the apparatus and method for detecting a PD signal according to embodiments of the present invention, since the PD coupler having high frequency characteristics and high sensitivity characteristics is connected to the ground side of the power device, damage of the power device and/or the PD coupler otherwise generated when the PD coupler is connected to a high voltage part of the power device can be prevented. Namely, in the apparatus and method for detecting a PD signal according to embodiments of the present invention, since the PD coupler is connected to the ground side of the power device, the PD coupler is not greatly affected by the capacity of a current applied to the power device.

In the apparatus and method for detecting a PD signal according to embodiments of the present invention, since the PD coupler is connected to the ground side (i.e., the ground side of the power device) having a relatively low voltage and a relatively low current in comparison to a high voltage part, the size of the PD coupler can be minimized and the PD coupler is low-priced.

In the apparatus and method for detecting a PD signal according to embodiments of the present invention, since the PD coupler is connected to the ground side of the power device to detect a PD signal, the PD coupler can be easily applied even to the power device that is in operation.

In the apparatus and method for detecting a PD signal according to embodiments of the present invention, a PD signal can be detected through the PD coupler without interruption to service work (or a dead-line work) with respect to the power device that is in operation.

Therefore, in the apparatus and method for detecting a PD signal according to embodiments of the present invention, a status of the high voltage power device can be easily monitored, and thus, the power device can be stably operated, and in the occurrence of an unexpected accident, a corresponding situation can be flexibly coped with or handled, maintenance can be smoothly performed, and reliability can be enhanced.

As the present invention may be embodied in several forms without departing from the characteristics thereof, it should also be understood that the above-described embodiments are not limited by any of the details of the foregoing description, unless otherwise specified, but rather should be construed broadly within its scope as defined in the appended claims, and therefore all changes and modifications that fall within the metes and bounds of the claims, or equivalents of such metes and bounds are therefore intended to be embraced by the appended claims.

What is claimed is:

1. An apparatus for detecting a partial discharge signal of a power device, the apparatus comprising:
a partial discharge (PD) coupler connected to a ground side of a power device, and configured to cancel a low frequency noise component including a commercial frequency from an alternative current (AC) component flowing through the ground side of the power device when a partial PD signal is generated from the power device, and allow a high frequency component including a PD signal included in the AC component to pass therethrough to generate a PD analog signal; and
a PD detection unit configured to cancel a noise signal from the PD analog signal generated by the PD coupler to detect only the PD signal.

2. The apparatus of claim 1, wherein the PD coupler is a coupling capacitor in which mica is laminated or a ceramic material is laminated.

3. The apparatus of claim 1, further comprising:
a display unit configured to display information corresponding to the PD signal on a screen.

4. The apparatus of claim 1, wherein the PD detection unit comprises:
a high frequency filter connected to the PD coupler and configured to cancel an external noise signal from the PD analog signal received from the PD coupler and output an analog signal including the PD signal;
an analog-to-digital (A/D) converter configured to convert the analog signal output from the high frequency filter into a digital signal;
a controller configured to detect the PD signal from the digital signal which has been converted by the A/D converter, and generate information corresponding to the detected PD signal; and
a display unit configured to display the information corresponding to the detected PD signal on a screen.

5. The apparatus of claim 4, wherein the information corresponding to the detected PD signal is a digital value corresponding to the detected PD signal or a signal graph corresponding to the detected PD signal.

6. A method for detecting a partial discharge signal of a power device, the method comprising:
when a partial discharge (PD) signal is generated from a power device through a PD coupler connected to a ground side of the power device, canceling a low frequency noise component including a commercial frequency from an AC component flowing through the ground side of the power device;
generating a PD analog signal by allowing a high frequency component including a PD signal included in the AC component to pass through the PD coupler connected to the ground side of the power device; and
canceling a noise signal from the generated PD analog signal to detect only the PD signal.

7. The method of claim 6, further comprising:
displaying the information corresponding to PD signal on a display unit.

8. The method of claim 6, wherein the detecting of only the PD signal comprises:
canceling an external noise signal from the PD analog signal received from the PD coupler to output an analog signal including the PD discharge signal;
converting the analog signal output from the high frequency filter into a digital signal;
detecting the PD signal from the digital signal and generating information corresponding to the detected PD signal; and
displaying the information corresponding to the detected PD signal on the display unit.

9. The method of claim 8, wherein the information corresponding to the detected PD signal is a digital value corresponding to the detected PD signal or a signal graph corresponding to the detected PD signal.
